(19) United States
(12) Patent Application Publication
(10) Pub. No.: US 2025/0013873 A1
(43) Pub. Date: Jan. 9, 2025

(54) METHOD, APPARATUS AND SYSTEM FOR CONSISTENCY ENHANCED LARGE LANGUAGE MODELS

(71) Applicant: SRI International, Menlo Park, CA (US)

(72) Inventors: Ajay DIVAKARAN, Monmouth Junction, NJ (US); Karan SIKKA, Robbinsville, NJ (US); Michael COGSWELL, Yardley, PA (US); Yunye GONG, West Windsor, NJ (US); Yangyi CHEN, Princeton, NJ (US)

(21) Appl. No.: 18/766,378

(22) Filed: Jul. 8, 2024

Related U.S. Application Data
(60) Provisional application No. 63/525,422, filed on Jul. 7, 2023.
(60) Provisional application No. 63/552,791, filed on Feb. 13, 2024.

(51) Int. Cl. G06N 3/098; G06F 30/27; G06F 40/40; G06N 3/0475

(52) U.S. Cl. CPC G06N 3/098; G06F 30/27; G06F 40/40; G06N 3/0475

(57) ABSTRACT

A method, apparatus, and system for training a language model for enhanced consistency include selecting at least a portion of the content data of the language model, generating reasoning statements in the form of natural language relevant to the selected portion of the content data, and training the language model using the generated reasoning statements such that a logical inference of the trained language model in response to a prompt directed to the selected portion of the content data is increased as compared with the logical inference of the language model in response to the same or similar prompt before the training of the language model to enhance the consistency of the language model with respect to the selected portion of the content data. The trained language model can be used to generate a logical inference having enhanced consistency for at least a portion of content data.

### CROSS-REFERENCE TO RELATED APPLICATIONS

This application claims benefit of and priority to U.S. Provisional Patent Application Ser. No. 63/525,422, filed Jul. 7, 2023 and U.S. Provisional Patent Application No. 63/552,791, filed Feb. 13, 2024.

### FIELD OF THE INVENTION

Embodiments of the present principles generally relate to the adaptation of language models and, more particularly, to a method, apparatus and system for enhancing consistency in language models, such as large language models (LLMs).

### BACKGROUND

Language models, such as large language models (LLMs) are being used with success in various applications for the processing of content data. However, current LLMs have a propensity to hallucinate, generating plausible sounding but incorrect outputs. That is, LLMs still do not show signs of human-like reasoning, which means that LLMs fail at tasks that require human like reasoning. Addressing hallucinations in LLMs is a nascent field. For the most part, hallucination correction is mostly manual and hence not scalable or efficient.

What is needed are language models that have the ability to parse natural queries about content and generate human-like outputs, such as reasoning consistency, based on the perceived information.

### SUMMARY

Embodiments of the present principles provide a method, apparatus, and system for enhancing consistency in language models, such as large language models (LLMs).

In some embodiments, a method for training a language model for enhanced consistency can include selecting at least a portion of the content data of the language model, generating reasoning statements in the form of natural language relevant to the selected portion of the content data, and training the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data

In some embodiments, a method for generating a logical inference having enhanced consistency for at least a portion of content data includes receiving a prompt directed to that at least the portion of the content data, and providing a logical inference in response to the received prompt for the at least the portion of the content data using an associated, trained language model, the language model having been trained by generating reasoning statements in the form of natural language relevant to the at least the portion of the content data, and training the language model using the generated reasoning statements such that a logical inference of the trained language model in response to the received prompt is increased as compared with the logical inference of the language model in response to the same or similar prompt before the training of the language model to enhance the consistency of the language model with respect to at least the at least portion of the content data.

In some embodiments, an apparatus for training a language model for enhanced consistency includes a processor and a memory accessible to the processor, the memory having stored therein at least one of programs or instructions. When the programs and instructions are executed by the processor, that apparatus is configured to select at least a portion of the content data of the language model, generate reasoning statements in the form of natural language relevant to the selected portion of the content data, and train the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data.

In some embodiments, a non-transitory computer readable medium having stored thereon at least one program, the at least one program including instructions which, when executed by a processor, cause the processor to perform a method for training a language model for enhanced consistency including selecting at least a portion of the content data of the language model, generating reasoning statements in the form of natural language relevant to the selected portion of the content data, and training the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data.

Other and further embodiments in accordance with the present principles are described below.

### BRIEF DESCRIPTION OF THE DRAWINGS

So that the manner in which the above recited features of the present principles can be understood in detail, a more particular description of the principles, briefly summarized above, may be had by reference to embodiments, some of which are illustrated in the appended drawings. It is to be noted, however, that the appended drawings illustrate only typical embodiments in accordance with the present principles and are therefore not to be considered limiting of its scope, for the principles may admit to other equally effective embodiments.

FIG. 1 depicts a high-level block diagram of a large language model (LLM) consistency system 100 for enhancing consistency in a LLM in accordance with at least one embodiment of the present principles.

FIG. 2 depicts a Table including examples of prompts and logical statements in accordance with an embodiment of the present principles.

FIG. 3 depicts content data of an LLM including a scene with a child sitting at a table that has, on top, a birthday cake with two candles on it.

FIG. 4 depicts a flow diagram of a method for enhancing consistency of a language model in accordance with an embodiment of the present principles.

FIG. 5 depicts a high-level block diagram of a computing device suitable for use with an LLM consistency system in accordance with embodiments of the present principles.

FIG. 6 depicts a high-level block diagram of a network in which embodiments of an LLM consistency system in accordance with the present principles can be applied.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present principles generally relate to methods, apparatuses and systems for enhancing consistency in language models, such as large language models (LLMs) and/or large language visual models (LLVMs). While the concepts of the present principles are susceptible to various modifications and alternative forms, specific embodiments thereof are shown by way of example in the drawings and are described in detail below. It should be understood that there is no intent to limit the concepts of the present principles to the particular forms disclosed. On the contrary, the intent is to cover all modifications, equivalents, and alternatives consistent with the present principles and the appended claims. For example, although embodiments of the present principles are described with respect to specific large language models and reasoning content such as logically related content data comprising text data, embodiments of the present principles can be implemented in substantially any language model and with any of at least text data, visual content data, and/or multimodal content data in accordance with the present principles.

In the teachings herein, the term “consistency” is intended to identify and define the ability of a language model to better understand and identify content data independent of how the language model is prompted/queried. That is, the term “consistency” is intended to define the ability of a language model to perform tasks requiring logic, calculation and decision-making by structuring the input in a way that mimics human reasoning. For example, in some embodiments, the term consistency, as used herein, is intended to define the ability of a language model to respond to prompts/queries from a forward and/or reverse logical direction, which can be considered at least one of a forward consistency and/or a reverse consistency. As such, in some embodiments of the present principles, “enhanced consistency” is intended to define and describe an increased level of logical inference reasoning and/or consistency of a language model after a training of the present principles as compared to the level of logical inference reasoning and/or consistency of the language model before the training of the present principles.

In the teachings herein, the phrase “reasoning statement” and derivatives thereof, are intended to identify and define content, such as textual, visual, and/or multimodal content, for example, in the form of at least one of natural language questions and/or related answers, and/or natural language prompts and/or related responses, and/or visual seed content, generated with the intention of being used to train a language model (e.g., an LLM or in the case of visual data/images an LLVM) to further and more deeply understand content associated with the language model, such that a consistency of the language model with respect to the associated content is enhanced/increased. For example, in some embodiments, reasoning statements can describe statements/data generated from content associated with a language model that is used to train a language model to enable the language model to perform tasks requiring logic, calculation and decision-making in a way that at least increases a level of inference reasoning and can mimic human reasoning. Examples of reasoning statements of the present principles are provided below.

Embodiments of the present principles provide a method, apparatus and system for enhancing consistency in, language models, such as large language models (LLM) and large language visual models (LLVM), while not changing the backbone of an LLM. In some embodiments, an adaptor module of the present principles is used to provide natural language reasoning statements, such as logically related content, which are used to fine tune an LLM to enhance consistency of the LLM with respect to its data. Alternatively or in addition, in some embodiments, a human-in-the-loop can used to provide reasoning statements of the present principles, such as chain of thought reasoning content, which can also be used to fine tune an LLM to enhance consistency of the LLM with respect to its data in accordance with the present principles.

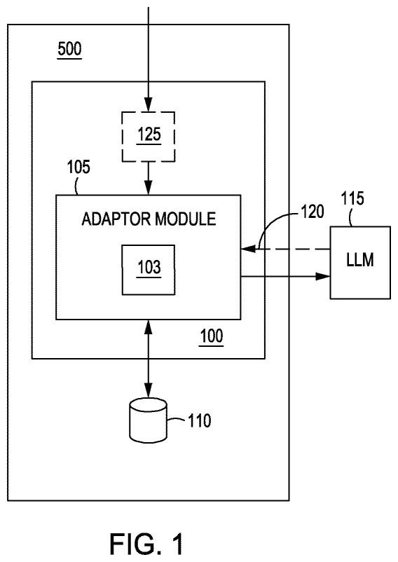

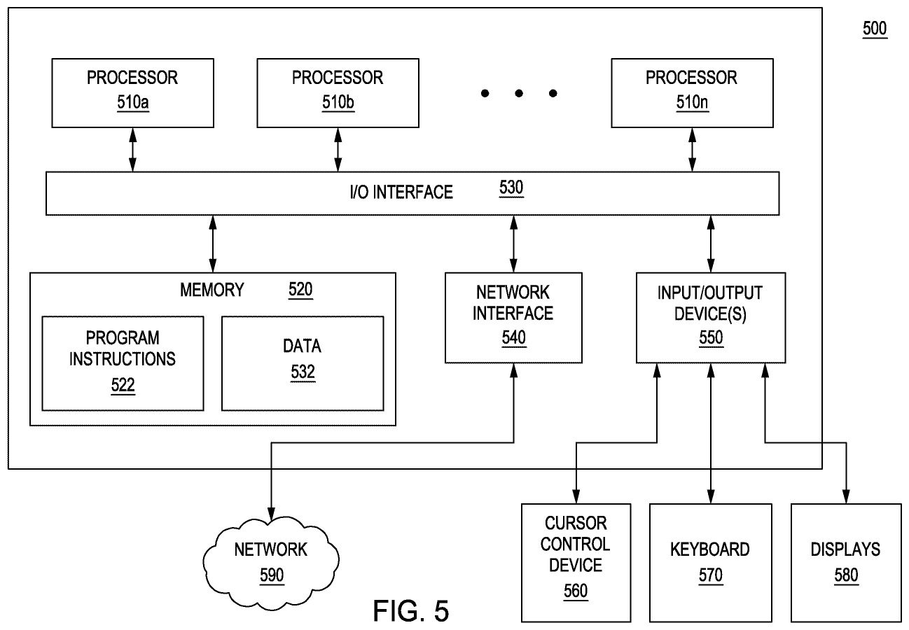

FIG. 1 depicts a high-level block diagram of a large language model (LLM) consistency system 100 for enhancing consistency in a language model, such as an LLM and/or an LLVM, in accordance with at least one embodiment of the present principles. The LLM consistency system 100 of FIG. 1 illustratively comprises an adaptor module 105, which, in the embodiment of the LLM consistency system 100 FIG. 1, is in communication with a database 110 and an LLM 115 (i.e., or an LLVM in embodiments in which content includes visual content). In the embodiment of FIG. 1, the LLM consistency system 100 further includes a machine learning (ML) model 103, an optional verification/feedback path 120 and an optional interface 125. In some embodiments of the present principles, the ML model 103 of the LLM consistency system 100 of FIG. 1 can comprise an LLM and/or an LLVM (e.g., a second LLM or second LLVM). In such embodiments, the LLM and/or LLVM 103 of the consistency system 100 can be implemented to provide content (i.e., reasoning statements in the form of text, visual content, and/or multimodal content) to be used to train the first LLM 115 and the adaptor 105 is used to train the first LLM 115 (described in greater detail below). As depicted in FIG. 1, embodiments of a system of the present principles, such as the LLM consistency system 100 of FIG. 1, can be implemented via a computing device 500 (described in greater detail below with reference to FIG. 5) in accordance with the present principles. Although in the embodiment of FIG. 1 the ML model 103 is depicted as being incorporated into the adaptor module 105, alternatively or in addition, in some embodiments the ML model 103 can comprise a separate component, for example, in some embodiments being implemented by the computing device 500. In addition, although in the embodiment of FIG. 1, the interface 125 is depicted as being a component of the LLM consistency system 100, alternatively or in addition, in some embodiments, the interface 125 can comprise a separate component, and in some embodiments, can comprise a component of the computing device 500.

In some embodiments of the present principles, a first LLM, such as the LLM 115, associated with the LLM consistency system 100 of FIG. 1, can be fine-tuned (e.g., trained) to be logically more self-consistent. For example, in some embodiments of the present principles, the adaptor module 105 of the LLM consistency system 100 of FIG. 1 can select a seed concept of the content of the LLM 115 for which to enhance consistency in accordance with the present principles. That is, in some embodiments, the adaptor module 105 of the LLM consistency system 100 of FIG. 1 can generate a natural language prompt/query for a seed concept of the content of the LLM 115 to be communicated to the LLM 115 to cause the LLM 115 to produce a response to the natural language prompt/query. Upon receiving the response from the LLM 115, the adaptor module 105 can generate reasoning statements, in this embodiment in the form of logically related prompts/queries, to prompt the LLM 115 to provide respective responses to the generated logically related prompts/queries. As previously recited above, in some embodiment, the adaptor module 105 can generates reasoning statements of the present principles by implementing the ML model 103, which in some embodiments can comprise a second LLM and/or second LLVM.

The reasoning statements, such as the logically related prompts/queries and respective responses, can then be used by the adaptor module 105 to train the LLM 115 to enhance the consistency of the responses from the LLM 115. That is, in some embodiments, the LLM 115 is prompted with each logically related prompt/query individually to assign a likelihood (e.g., probability), resulting in a logic program. The probability of the resulting logic program can then be maximized by adjusting the probability that a model places on each logically related prompt/query appropriately in a differentiable fashion using a probabilistic data space/language, such as Scallop. The result is that the LLM/model learns to be self-consistent about its knowledge of particular seed concepts. Although in the above embodiment it is described that the adapter module 105 generates an original prompt and/or including reasoning statements, in some embodiments of the present principles, an adaptor module of the present principles can instead select an original prompt and reasoning statements based on a response to the original prompt, from a database associated with the adaptor module, such as the database 110. The selected original prompt and the reasoning statements can then be used to train the LLM 115 for enhanced consistency in accordance with the present principles.

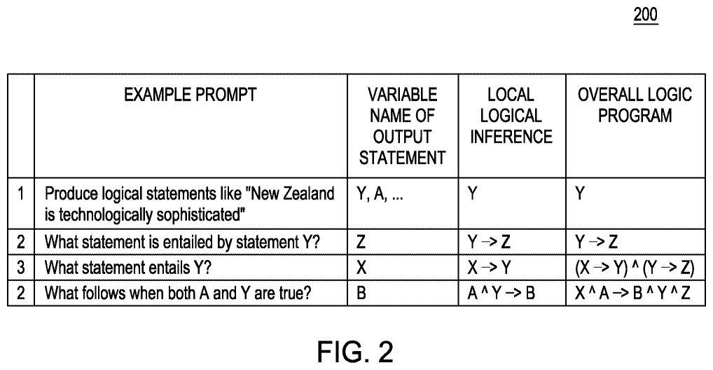

FIG. 2 depicts a Table 200 including examples of reasoning statements determined by an adaptor module of the present principles, such as logically related prompts/queries and respective responses in accordance with an embodiment of the present principles. For example, a first column of the first row of the Table 200 of FIG. 2 recites the reasoning statement “New Zealand is technologically sophisticated”. In a second column of the first row, the reasoning statement “New Zealand is technologically sophisticated” of the first row is associated with a variable name for the output statement of “Y, A, . . . ”. In a third column of the first row, a local logical inference is defined as “Y” and in a fourth column of the first row, the overall logic program is defined as “Y”.

In a second row of the Table 200 of FIG. 2, the example reasoning statement recites “What statement is entailed by statement Y?”. In a second column of the second row, a variable name for the output statement “Z” is assigned to the reasoning statement “What statement is entailed by statement Y?”. In a third column of the second row, a local logical inference is defined as “Y->Z” and in a fourth column of the second row, the overall logic program is defined as “Y->Z”.

In a third row of the Table 200 of FIG. 2, the example reasoning statement recites “What statement entails Y?”. In a second column of the third row, a variable name for the output statement, “X”, is assigned to the reasoning statement “What statement entails Y?”. In a third column of the second row, a local logical inference is defined as “X->Y” and a fourth column follows a similar convention as depicted in FIG. 2.

In a fourth row of the Table 200 of FIG. 2, the example reasoning statement recites “What follows when both A and Y are true?”. In a second column of the fourth row, a variable name for the output statement, “B”, is assigned to the reasoning “What follows when both A and Y are true?”. In a third column of the fourth row, a local logical inference is defined as “A\hat{ }Y->B” and in a fourth column of the second row, the overall logic program is defined as “X\hat{ }A->B\hat{ }Y\hat{ }Z”.

In general, as depicted in the Table 200 of FIG. 2, embodiments of the present principles generate a program that describes how the LLM “thinks” the statement Y is related to other things. To generate that program, in each row the original statement is expanded using a local operation. In row 2, a prompt is applied, for example “What statement is entailed by statement Y?” To produce Y->Z where Z is the response that the LLM gives to the prompt. The result is the logical relation because the prompt was designed specifically to only generate responses, Z, that have that particular logical relation to Y.

In some embodiments and in the embodiment depicted in the Table 200 of FIG. 2, the first set of reasoning statements, illustratively the locally related prompts/queries, used to construct the overall logic statement implies that the logical relationship should hold with probability 1.0, while the other statement-wise prompts/queries implicitly place a probability (almost certainly less than 1.0) on exactly the same logical relationship. The difference between these two probabilities can be thought of as a quantification of how self-consistent the LLM/model is. If the probabilities are very different, then the LLM/model is very inconsistent with itself and vice versa. In some embodiments, by seeding the example prompts with entities like “New Zealand” and “technologically sophisticated”, the kinds of self-consistency evaluated in local subject areas can be focused on those that are most relevant to the hallucination problem.

In some embodiments of the present principles, the reasoning statements, illustratively the logically related prompts/queries generated by the adaptor module 105, can be predetermined and stored in database accessible to the adaptor module 105. As such, upon receiving a response(s) from the LLM 115 after the initial prompting of the LLM 115, the adaptor module 105 can review the response and select from a database, such as the database 110 of FIG. 1, previously determined and stored logically related prompts/queries with which to further prompt the LLM 115 in accordance with the present principles and as described above.

Alternatively or in addition, in some embodiments of the present principles, an adaptor module of the present principles can include a machine learning model/system for generating the reasoning content, such as the logically related prompts/queries described above. For example and with reference to the LLM consistency system 100 of FIG. 1, the adaptor module 105 can implement the machine learning (ML) model 103 that is trained to automatically generate reasoning statements, such as additional logically related prompts/queries, based on a received response from the LLM 115 to an initial prompt/query. As such, upon receiving a response from the LLM 115, after initially prompting the LLM 115, the ML model 103 of the adaptor module 105 can generate reasoning content, such as the logically related prompts/queries, with which to prompt the LLM 115 as described above. As previously described above, in some embodiments of the present principles, the ML model 103 can comprise a second LLM and/or a second LLVM.

That is, an ML model/system of the present principles, such as the ML model 103 of the adaptor module 105 of the LLM consistency system 100 of FIG. 1, can be trained using a plurality (e.g., hundreds, thousands, millions) of instances of labeled content in which the training data comprises a plurality of data content provided by an LLM, such as the LLM 115, and associated reasoning statements, such as the logically related prompts/queries described above with respect to FIG. 2, to train an ML model/system of the present principles to generate logically related prompts/queries with which to prompt the LLM 115 to generate responses to the prompts/queries, the resulting logically related prompts/queries and respective responses to be used to train the LLM 115 to be more consistent in accordance with the present principles and as described above and in accordance with the present principles.

In some embodiments of the present principles, an adaptor module of the present principles, such as the adaptor module 105 of the LLM consistency system 100 of FIG. 1, can generate reasoning statements without the necessity of initially prompting the LLM for a response. That is, in some embodiments of the present principles, the adaptor module 105 can select at least a portion of the content (e.g., seed concept) of the LLM 115 for which the consistency of the LLM 115 is to be enhanced. The adaptor module 105 can then generate reasoning statements for the selected content. For example, in some embodiments of the present principles, an adaptor module of the present principles can implement a machine learning model/system for generating reasoning statements, such as logically related prompts and relative queries and/or questions and relative answers (as described above), from the content data of an LLM to be used to train the LLM to enhance the consistency of the LLM with respect to the selected content. For example and with reference to the LLM consistency system 100 of FIG. 1, the adaptor module 105 can implement the ML model 103 that is trained to generate reasoning statements, such as logically related prompts and relative responses and/or questions and relative answers (as described above), from the content data of the LLM 115, the reasoning statements intended to be used to train the LLM 115 to enhance the consistency of the LLM 115. As described above, in some embodiments, the ML model 103 can be a multi-layer neural network comprising nodes that are trained to have specific weights and biases. In some embodiments, the ML model 103 employs artificial intelligence techniques or machine learning techniques to analyze neural networks. In some embodiments in accordance with the present principles, suitable machine learning techniques can be applied to learn commonalities in sequential application programs and for determining from the machine learning techniques at what level sequential application programs can be canonicalized. In some embodiments, machine learning techniques that can be applied to learn commonalities in sequential application programs can include, but are not limited to, regression methods, ensemble methods, or neural networks and deep learning such as ‘Se2oSeq’ Recurrent Neural Network (RNNs)/Long Short-Term Memory (LSTM) networks, Convolution Neural Networks (CNNs), graph neural networks applied to the abstract syntax trees corresponding to the sequential program application, Transformers, such as encoder-only and decoder-only Transformers, NB Transformers, and the like. In some embodiments a supervised ML classifier could be used such as, but not limited to, Multilayer Perceptron, Random Forest, Naive Bayes, Support Vector Machine, Logistic Regression and the like. In addition, in some embodiments, the ML algorithm of the present principles can implement at least one of a sliding window or sequence-based techniques to analyze data.

An ML model/system of the present principles, such as the ML model 103 of the adaptor module 105 of the LLM consistency system 100 of FIG. 1 can be trained using a plurality (e.g., hundreds, thousands, millions) of instances of labeled content in which the training data comprises a plurality of content data (e.g., text data, video data, multimodal data that can comprise an LLM and/or an LLVM) and associated, labeled reasoning statements, such as logically related prompts and relative responses and/or questions and relative answers, defining/identifying properties of the selected content data, the selected content and associated reasoning data to be used train an ML model/system of the present principles to automatically generate reasoning statements from the selected content data for training an LLM to enhance a consistency of the LLM in accordance with the present principles.

Although in the above embodiment it is described that the adapter module 105 generates reasoning statements, in some embodiments of the present principles, an adaptor module of the present principles can instead select reasoning statements based on at least a portion of selected content from the LLM, from a database associated with the adaptor module, such as the database 110. The selected reasoning statements can then be used to train the LLM 115 for enhanced consistency in accordance with the present principles.

Alternatively or in addition, in some embodiments, a LLM consistency system of the present principles, such as the LLM consistency system 100 of FIG. 1, can include at least one human in the loop to generate reasoning statements of the present principles from content data of the LLM 115, to be used to enhance a consistency (i.e., knowledge/understanding) of the LLM 115 for the content data of the LLM 115. That is, in some embodiments, human assistance is incorporated into a LLM consistency system of the present principles for providing reasoning statements, such as questions and relative answers and/or prompts and relative responses for content data of an LLM, enabling LLMs to efficiently generate high-quality datasets. In some embodiments, the reasoning statements of the present principles can include chain-of-thought reasoning statements, examples of which are described below. More specifically, in some embodiments, a human in the loop can provide questions/answers and/or prompts/responses to be communicated to an LLM intended to improve a performance of the LLM in accordance with the present principles.

For example and as depicted in FIG. 1, the LLM consistency system 100 includes an optional interface 125 for human interaction with the LLM consistency system 100. In some embodiments the interface 125 can include an input device of the computing device 500. Embodiments of the present principles introduce a training stage for the LLM 115 that integrates human interaction for generating logic rationales that are sophisticated, consistent, and firmly grounded in the content data of the LLM 115.

In some embodiments, a user (e.g., human) of an LLM consistency system of the preset principles, such as the LLM consistency system 100 of FIG. 1, can generate a series of reasoning statements, such as questions and relative answers forming a chain of reasoning, that are based on a description of at least a selected portion of the content data of the LLM 115. The generated reasoning statements can then be communicated to the adaptor module 105, for example, using the optional interface 125 in communication with the adaptor module 105. For example, in an example in which content data of the LLM 115 contains a scene including patches of snow spread throughout grass on the side of a freeway, a human can generate the following series of reasoning statements intended to train the LLM 115 for enhanced consistency:
Q1: What Is seen on the grass on the side of the freeway?
A1: Patches of snow.
Q2: What kind of weather conditions could cause patches of snow to appear?
A2: Cold weather.
Q3: How can cold weather and patches of snow affect the conditions of a location?
A3: Hazardous conditions.

The reasoning statements, in the embodiment above in the form of questions and answers, generated by the human are then used by, for example the adaptor module 105, to train the LLM 115 to make higher level logical inferences about content data as compared to before the LLM 115 was trained, such as that cold weather is causing hazardous conditions at a location of a scene, to enhance the consistency of the LLM 115. Specifically, in the example above, the first question is a perceptual question generated based on the visual information in the scene. The second question is a question generated about the visual reasoning based on the previous perceived information. The LLM 115 can then make the high-level inference that cold weather can cause hazardous conditions at the location in the scene.

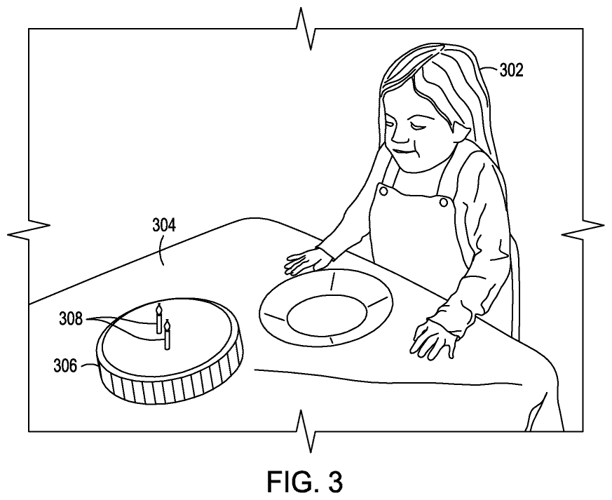

In another example depicted in FIG. 3, content data of the LLM 115 contains a scene including a child 302 sitting at a table 304 that has, on top, a birthday cake 306 with two candles 308 on it. In some embodiments, a human can generate the following series of reasoning statements, illustratively in the form of questions and answers for the scene to be used to train the LLM 115 for enhanced consistency in accordance with the present principles:
Q1: What Is on the cake?
A1: Two candles.
Q2: What does each candle represent?
A2: One year in age.
Q3: How old is the girl?
A3: The girl is two (2) years old.

The questions and answers generated by the human in the example of FIG. 3 comprise an example of chain of thought reasoning which is intended to be used by, for example the adaptor module 105, to train the LLM 115 to make logical inferences about content data, such as that two candles on a cake mean that a person in the scene is turning two (2) years old. Such training in accordance with the present principles is intended to enhance the consistency of the LLM 115 to enable the LLM to make high level inferences regarding the content of the LLM consistent with human reasoning. In some embodiments, such training ensures that a trained LLM of the present principles includes forward reasoning consistency and reverse/backwards reasoning consistency. More specifically, an LLM, such as the LLM 115 of FIG. 1, can be trained in accordance with the present principles by, for example the adaptor module 105, to infer from a scene of a little girl near a birthday cake with two candles that the little girl is turning two (2) years old (i.e., forward reasoning consistency), and similarly can infer from a scene including a little girl that is turning two (2) years old that a birthday cake for the little girl should include two candles (i.e., reverse/backwards reasoning consistency).

In some embodiments, a LLM consistency system of the present principles can include an optional verification/feedback path. For example, in the LLM consistency system 100 of FIG. 1, after the LLM 115 is trained in accordance with the present principles and as described herein, the LLM 115 can receive a prompt and provide a response to the prompt. The response to the prompt from the LLM 115 can be provided/fed back to the adaptor module 105 via the optional verification/feedback path 120. In some embodiments of the present principles, the initial prompt received by the LLM 115 can be provided by the adaptor module 105, for example during a test mode, to be used to evaluate the accuracy of the response to the prompt from the LLM 115. Alternatively or in addition, in some embodiments, an initial prompt to be communicated to the LLM can be provided by a user of the LLM 115 via, for example, the interface 125, either during a test mode and/or during a normal operation of the LLM 115.

In such embodiments, the adaptor module 105 can have knowledge of a target response, which in some embodiments can include a ground truth, to an initial prompt communicated to a trained LLM by, for example, having such information stored in a storage device, such as the database 110, that is accessible by the adaptor module 105. In some embodiments, the adaptor 105 compares a response from the LLM 115 to the initial prompt to an expected target response (e.g. ground truth) to verify if the response to the prompt from the LLM 115 accurately (e.g., within a tolerance) depicts the expected target response. In some embodiments, accuracy-related information of the response to the prompt from the LLM 115 determined by the adaptor module 105 can be communicated to the LLM 115 to further train the LLM 115 for increasing consistency and accuracy of responses to prompts by the LLM 115.

For example, in some embodiments an accuracy threshold can be set by, for example the adaptor module 105 of the LLM consistency system 100 of FIG. 1, above which responses to prompts from the LLM 115 can be considered accurate and below which responses to prompts from the LLM 115 can be considered inaccurate. Such information can be communicated to the LLM 115 to encourage the LLM 115 to produce responses to prompts that are considered accurate and discourage the LLM 115 from producing responses to prompts that are considered inaccurate.

Although in the above described embodiment, the adaptor module 105 is described as generating a prompt and comparing a target response (e.g., ground truth) to a response by the trained LLM 115 to the prompt, alternatively or in addition, in some embodiments, the human (e.g., user of the system of the present principles) can instead be used to provide the above described initial prompt and can compare a response by the trained LLM 115 to the initial prompt to a target response to determine a degree to which the response from the trained LLM 115 reflects the target response. In such embodiments of the present principles, the human can then provide feedback information to the LLM 115 to be used to adjust the accuracy of the LLM 115 to increase the accuracy of the response of the LLM 115 to prompts in accordance with the present principles.

For example, in such embodiments, the human in the loop can select content of an LLM 115 and direct an initial prompt (data set prompt) to the LLM 115 directed to the selected content using, for example the interface 125, and communicated through the adaptor module 105. The LLM 115 can then generate a response to the prompt and the response can be provided to the human, for example, using a display associated with the computing device 500. In some embodiments, the human can then evaluate the response for accuracy (e.g., errors) by comparing the response to a target response (i.e., in some embodiments a stored ground truth) and can inform the LLM 115 of the errors (i.e., differences between the target response and a response from the LLM to the prompt) for correction of the LLM 115 by, for example, retraining the LLM 115 using the content of the target response. Alternatively or in addition, in some embodiments, the LLM 115 can rewrite the initial prompt to cause the LLM 115 to generate a response closer to the target/ground truth of the response from the LLM 115. In some embodiments, the process can be repeated until a threshold has been satisfied or until the human in the loop is satisfied.

In some embodiments of the present principles, a first LLM, such as the LLM 115 of FIG. 1, can be trained for improved accuracy with a target response by using conditional reinforcement learning, which incudes cross entropy loss or next token prediction. Given a prompt, a target/ground truth response given during training is attempted to be generated. In some embodiments, the natural language modeling approach of the present principles adds a <good> or <bad> token during training and includes some examples in which the response is actually a bad response to the prompt to train the LLM based on bad responses.

In some embodiments of the present principles, to further increase a consistency/accuracy of a response from a trained LLM, such as the LLM 115 associated with the LLM consistency system 100 of FIG. 1, to a received prompt, the adaptor module 105 can retrieve content data of the LLM 115 relevant to at least a desired concept received in, for example, a prompt intended for the LLM. For example, in some embodiments the relevant content data/documents of the LLM 115 can be segmented into shorter snippets (e.g., paragraph length snippets) using simple rules that can be contained in the adaptor module 105. In some embodiments, such simple rules can be entered/programmed into the adaptor module 105 by a user of the LLM consistency system 100 via, for example, an input device of the computing device 500 (described in further detail below with respect to FIG. 5). The snippets, generated from the relevant content data/documents of the LLM 115, are converted into respective vector representations of the snippets and the vectors representations are embedded using the LLM 115 to form a database (e.g., an embedding space), such as the database 110, of paragraphs that express potentially relevant content/documents and descriptions of information regarding at least a location of the corresponding embeddings in the embedding space. In accordance with the present principles, the LLM 115 is, as such, trained for factual consistency.

After the consistency training of the LLM 115 in accordance with the present principles, when a new prompt is received by the, now trained LLM 115, a vector representation can be created for the content data of the prompt and the vector representation of the prompt is projected into the same embedding space using a neural network, such as the LLM 115 or the optional ML system 103 associated with the adaptor module 105. In accordance with embodiments of the present principles, relevant snippets can be retrieved from the database/embedding space 110 based on a similarity in the embedding space of the project prompt content to content embedded in the embedding space 110. That is, in some embodiments, the retrieval of similar snippets of the present principles results in K most relevant documents/content similar to the content in the prompt based on content embedded in the embedding space. The retrieved content can then be added as additional context to the received prompt intended for the LLM 115.

By adding the additional context to a prompt in accordance with the present principles, downstream components (e.g., a LLM) can benefit from a corpus of relevant knowledge without explicitly including it. Furthermore, while some downstream components do explicitly represent the corpus using a structured knowledge base, the incorporation of the additional external information is unstructured, thus allowing downstream components to capture elements of the corpus that aren't easily encoded in a structured fashion.

In some embodiments, limitations/rules can be added by, for example, the adaptor module 105 to the additionally retrieved content of the present principles. For example, for time sensitive materials, such as news articles, what was true/accurate during a previous time period (e.g., 5 or 10 years ago) may no longer be true for a current time period. For example, evidence that supports ISIS being in decline in 2019 should not be confused with evidence that shows a potential resurgence in 2020. In some embodiments, such issues are addressed by retrieving only a subset of the corpus which complies with the applied limitations/rules, such as retrieving only relatively time insensitive content (e.g., encyclopedia articles) or content that is restricted to a defined time period. That is, in some embodiments, a content/snippet retrieval step of the present principles can be guided based on both relevance and time as defined by limitations/rules in accordance with the present principles.

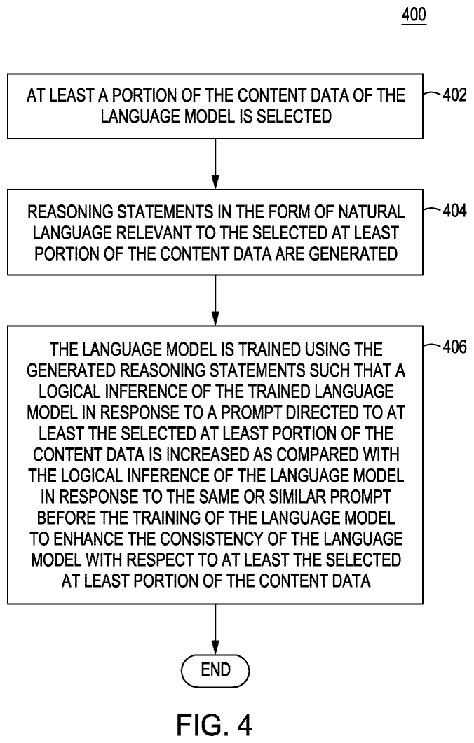

FIG. 4 depicts a flow diagram of a method 400 for training a language model for enhanced consistency in accordance with an embodiment of the present principles. The method 400 can begin at 402 during which at least a portion of the content data of the language model is selected. The method 400 can proceed to 404.

At 404, reasoning statements in the form of natural language relevant to the selected at least portion of the content data are generated. The method 400 can proceed to 406.

At 406, the language model is trained using the generated reasoning statements such that a logical inference of the trained language model in response to a prompt directed to at least the selected at least portion of the content data is increased as compared with the logical inference of the language model in response to the same or similar prompt before the training of the language model to enhance the consistency of the language model with respect to at least the selected at least portion of the content data.

The method 400 can then be exited.

In some embodiments, in the method 400 the reasoning statements include at least one of logically related statements or chain of thought reasoning statements identifying properties of the selected portion of the content data.

In some embodiments, in the method 400 the reasoning statements are generated by at least one of a human or a machine learning model.

In some embodiments, the method 400 can further include responding to a prompt for information using the trained language model, and verifying if the response to the prompt is within a threshold of a target response to the prompt.

In some embodiments, the method 400 can further include receiving at least one prompt originating from a human intended for the language model, generating an inference in response to the at least one prompt using the language model, receiving information from the human indicating if the generated inference is within a threshold of a target inference of a response to the at least one prompt, and if the generated inference is not within the threshold, providing training data to the language model to train the language model to generate an inference that is within the threshold of the target inference.

In some embodiments, in the method 400 the receiving at least one prompt, the generating an inference, the receiving information, and the providing training data are repeated until an inference is generated by the language model that is within the threshold of the target inference.

In some embodiments, the method 400 further includes receiving a prompt for information, determining a vector representation for at least a portion of the content data contained in the prompt, projecting the vector representation into an embedding space in which content data of a language model for which the prompt is intended is embedded, determining nearest neighbor content data for the vector representation in the embedding space, and including the nearest neighbor content data in the prompt intended for the language model.

In some embodiments, a method for generating a logical inference having enhanced consistency for at least a portion of content data includes receiving a prompt directed to the at least the portion of the content data, and providing a logical inference in response to the received prompt for the at least the portion of the content data using an associated, trained language model, the language model having been trained by generating reasoning statements in the form of natural language relevant to the at least the portion of the content data, and training the language model using the generated reasoning statements such that a logical inference of the trained language model in response to the received prompt is increased as compared with the logical inference of the language model in response to the same or similar prompt before the training of the language model to enhance the consistency of the language model with respect to at least the at least portion of the content data.

In some embodiments, an apparatus for training a language model for enhanced consistency includes a processor, and a memory accessible to the processor, the memory having stored therein at least one of programs or instructions. In some embodiments, when the programs or instructions are executed by the processor, the apparatus is configure to select at least a portion of the content data of the language model, generate reasoning statements in the form of natural language relevant to the selected portion of the content data, and train the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data.

In some embodiments, in the apparatus the reasoning statements comprise at least one of logically related statements or chain of thought reasoning statements identifying properties of the selected portion of the content data.

In some embodiments, in the apparatus the reasoning statements are generated by at least one of a human or a machine learning model.

In some embodiments, the apparatus is further configured to respond to a prompt for information using the trained language model, and verify if the response to the prompt is within a threshold of a target response to the prompt.

In some embodiments, the apparatus is further configured to receive at least one prompt originating from a human and intended for the language model, generate an inference in response to the at least one prompt using the language model, receive information from the human indicating if the generated inference is within a threshold of a target inference of a response to the at least one prompt, and if the generated inference is not within the threshold, provide training data to the language model to train the language model to generate an inference that is within the threshold of the target inference.

In some embodiments, in the apparatus, the receiving at least one prompt, the generating an inference, the receiving information, and the providing training data are repeated until an inference is generated by the language model that is within the threshold of the target inference.

In some embodiments, a non-transitory computer readable medium having stored thereon at least one program, the at least one program including instructions which, when executed by a processor, cause the processor to perform a method for training a language model for enhanced consistency including selecting at least a portion of the content data of the language model, generating reasoning statements in the form of natural language relevant to the selected portion of the content data, and training the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data.

In some embodiments, in the non-transitory computer readable medium the reasoning statements comprise at least one of logically related statements or chain of thought reasoning statements identifying properties of the selected portion of the content data.

In some embodiments, in the non-transitory computer readable medium the reasoning statements are generated by at least one of a human or a machine learning model.

In some embodiments, the method of the non-transitory computer readable medium further includes receiving at least one prompt originating from a human and intended for the language model, generating an inference in response to the at least one prompt using the language model, receiving information from the human indicating if the generated inference is within a threshold of a target inference of a response to the at least one prompt, and if the generated inference is not within the threshold, providing training data to the language model to train the language model to generate an inference that is within the threshold of the target inference.

In some embodiments, in the non-transitory computer readable medium the receiving at least one prompt, the generating an inference, the receiving information, and the providing training data are repeated until an inference is generated by the language model that is within the threshold of the target inference.

In some embodiments, the method of the non-transitory computer readable medium further comprises receiving a prompt for information, determining a vector representation for at least a portion of the content data contained in the prompt, projecting the vector representation into an embedding space in which content data of a language model for which the prompt is intended is embedded, determining nearest neighbor content data for the vector representation in the embedding space, and including the nearest neighbor content data in the prompt intended for the language model.

As depicted in FIG. 1, embodiments of a LLM consistency system of the present principles, such as the LLM consistency system 100 of FIG. 1, can be implemented in a computing device 500 in accordance with the present principles. That is, in some embodiments, data can be communicated to, for example, the adaptor module 105 of the LLM consistency system 100 of FIG. 1 using the computing device 500 via, for example, any input/output means associated with the computing device 500. Data associated with a graphical representation formulation system in accordance with the present principles can be presented to a user using an output device of the computing device 500, such as a display, a printer or any other form of output device.

For example, FIG. 5 depicts a high-level block diagram of a computing device 500 suitable for use with embodiments of a LLM consistency system in accordance with the present principles, such as the LLM consistency system 100 of FIG. 1. In some embodiments, the computing device 500 can be configured to implement methods of the present principles as processor-executable program instructions 522 (e.g., program instructions executable by processor(s) 510) in various embodiments.

In the embodiment of FIG. 5, the computing device 500 includes one or more processors 510a-510n coupled to a system memory 520 via an input/output (I/O) interface 530. The computing device 500 further includes a network interface 540 coupled to I/O interface 530, and one or more input/output devices 550, such as cursor control device 560, keyboard 570, and display(s) 580. In various embodiments, a user interface can be generated and displayed on display 580. In some cases, it is contemplated that embodiments can be implemented using a single instance of computing device 500, while in other embodiments multiple such systems, or multiple nodes making up the computing device 500, can be configured to host different portions or instances of various embodiments. For example, in one embodiment some elements can be implemented via one or more nodes of the computing device 500 that are distinct from those nodes implementing other elements. In another example, multiple nodes may implement the computing device 500 in a distributed manner.

In different embodiments, the computing device 500 can be any of various types of devices, including, but not limited to, a personal computer system, desktop computer, laptop, notebook, tablet or netbook computer, mainframe computer system, handheld computer, workstation, network computer, a camera, a set top box, a mobile device, a consumer device, video game console, handheld video game device, application server, storage device, a peripheral device such as a switch, modem, router, or in general any type of computing or electronic device.

In various embodiments, the computing device 500 can be a uniprocessor system including one processor 510, or a multiprocessor system including several processors 510 (e.g., two, four, eight, or another suitable number). Processors 510 can be any suitable processor capable of executing instructions. For example, in various embodiments processors 510 may be general-purpose or embedded processors implementing any of a variety of instruction set architectures (ISAs). In multiprocessor systems, each of processors 510 may commonly, but not necessarily, implement the same ISA.

System memory 520 can be configured to store program instructions 522 and/or data 532 accessible by processor 510. In various embodiments, system memory 520 can be implemented using any suitable memory technology, such as static random-access memory (SRAM), synchronous dynamic RAM (SDRAM), nonvolatile/Flash-type memory, or any other type of memory. In the illustrated embodiment, program instructions and data implementing any of the elements of the embodiments described above can be stored within system memory 520. In other embodiments, program instructions and/or data can be received, sent or stored upon different types of computer-accessible media or on similar media separate from system memory 520 or computing device 500.

In one embodiment, I/O interface 530 can be configured to coordinate I/O traffic between processor 510, system memory 520, and any peripheral devices in the device, including network interface 540 or other peripheral interfaces, such as input/output devices 550. In some embodiments, I/O interface 530 can perform any necessary protocol, timing or other data transformations to convert data signals from one component (e.g., system memory 520) into a format suitable for use by another component (e.g., processor 510). In some embodiments, I/O interface 530 can include support for devices attached through various types of peripheral buses, such as a variant of the Peripheral Component Interconnect (PCI) bus standard or the Universal Serial Bus (USB) standard, for example. In some embodiments, the function of I/O interface 530 can be split into two or more separate components, such as a north bridge and a south bridge, for example. Also, in some embodiments some or all of the functionality of I/O interface 530, such as an interface to system memory 520, can be incorporated directly into processor 510.

Network interface 540 can be configured to allow data to be exchanged between the computing device 500 and other devices attached to a network (e.g., network 590), such as one or more external systems or between nodes of the computing device 500. In various embodiments, network 590 can include one or more networks including but not limited to Local Area Networks (LANs) (e.g., an Ethernet or corporate network), Wide Area Networks (WANs) (e.g., the Internet), wireless data networks, some other electronic data network, or some combination thereof. In various embodiments, network interface 540 can support communication via wired or wireless general data networks, such as any suitable type of Ethernet network, for example; via digital fiber communications networks; via storage area networks such as Fiber Channel SANs, or via any other suitable type of network and/or protocol.

Input/output devices 550 can, in some embodiments, include one or more display terminals, keyboards, keypads, touchpads, scanning devices, voice or optical recognition devices, or any other devices suitable for entering or accessing data by one or more computer systems. Multiple input/output devices 550 can be present in computer system or can be distributed on various nodes of the computing device 500. In some embodiments, similar input/output devices can be separate from the computing device 500 and can interact with one or more nodes of the computing device 500 through a wired or wireless connection, such as over network interface 540.

Those skilled in the art will appreciate that the computing device 500 is merely illustrative and is not intended to limit the scope of embodiments. In particular, the computer system and devices can include any combination of hardware or software that can perform the indicated functions of various embodiments, including computers, network devices, Internet appliances, PDAs, wireless phones, pagers, and the like. The computing device 500 can also be connected to other devices that are not illustrated, or instead can operate as a stand-alone system. In addition, the functionality provided by the illustrated components can in some embodiments be combined in fewer components or distributed in additional components. Similarly, in some embodiments, the functionality of some of the illustrated components may not be provided and/or other additional functionality can be available.

The computing device 500 can communicate with other computing devices based on various computer communication protocols such a Wi-Fi, Bluetooth.R™. (and/or other standards for exchanging data over short distances includes protocols using short-wavelength radio transmissions), USB, Ethernet, cellular, an ultrasonic local area communication protocol, etc. The computing device 500 can further include a web browser.

Although the computing device 500 is depicted as a general-purpose computer, the computing device 500 is programmed to perform various specialized control functions and is configured to act as a specialized, specific computer in accordance with the present principles, and embodiments can be implemented in hardware, for example, as an application specified integrated circuit (ASIC). As such, the process steps described herein are intended to be broadly interpreted as being equivalently performed by software, hardware, or a combination thereof.

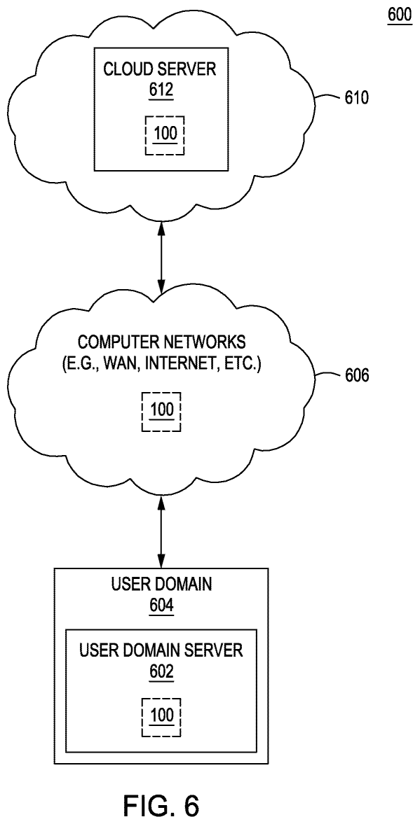

FIG. 6 depicts a high-level block diagram of a network in which embodiments of a LLM consistency system in accordance with the present principles, such as the LLM consistency system 100 of FIG. 1, can be applied. The network environment 600 of FIG. 6 illustratively comprises a user domain 602 including a user domain server/computing device 604. The network environment 600 of FIG. 6 further comprises computer networks 606, and a cloud environment 610 including a cloud server/computing device 612.

In the network environment 600 of FIG. 6, a system for enhancing a consistency of a language model in accordance with the present principles, such as the LLM consistency system 100 of FIG. 1, can be included in at least one of the user domain server/computing device 604, the computer networks 606, and the cloud server/computing device 612. That is, in some embodiments, a user can use a local server/computing device (e.g., the user domain server/computing device 604) to provide related logical statements such as questions and relative answers for a language model to enhance the consistency of the language model in accordance with the present principles.

In some embodiments, a user can implement a system for enhancing the consistency of a language model in the computer networks 606 to provide related logical statements such as questions and relative answers for a language model to enhance the consistency of the language model in accordance with the present principles. Alternatively or in addition, in some embodiments, a user can implement a system for enhancing the consistency of a language model in the cloud server/computing device 612 of the cloud environment 610 in accordance with the present principles. For example, in some embodiments it can be advantageous to perform processing functions of the present principles in the cloud environment 610 to take advantage of the processing capabilities and storage capabilities of the cloud environment 610. In some embodiments in accordance with the present principles, a system for enhancing the consistency of a language model can be located in a single and/or multiple locations/servers/computers to perform all or portions of the herein described functionalities of a system in accordance with the present principles. For example, in some embodiments components of a the LLM consistency system of the present principles, such as the adaptor module 105 of the LLM consistency system 100 of FIG. 1, can be located in one or more than one of the user domain 602, the computer network environment 606, and the cloud environment 610 for providing the functions described above either locally and/or remotely and/or in a distributed manner.

Those skilled in the art will also appreciate that, while various items are illustrated as being stored in memory or on storage while being used, these items or portions of them can be transferred between memory and other storage devices for purposes of memory management and data integrity. Alternatively, in other embodiments some or all of the software components can execute in memory on another device and communicate with the illustrated computer system via inter-computer communication. Some or all of the system components or data structures can also be stored (e.g., as instructions or structured data) on a computer-accessible medium or a portable article to be read by an appropriate drive, various examples of which are described above. In some embodiments, instructions stored on a computer-accessible medium separate from the computing device 500 can be transmitted to the computing device 500 via transmission media or signals such as electrical, electromagnetic, or digital signals, conveyed via a communication medium such as a network and/or a wireless link. Various embodiments can further include receiving, sending or storing instructions and/or data implemented in accordance with the foregoing description upon a computer-accessible medium or via a communication medium. In general, a computer-accessible medium can include a storage medium or memory medium such as magnetic or optical media, e.g., disk or DVD/CD-ROM, volatile or non-volatile media such as RAM (e.g., SDRAM, DDR, RDRAM, SRAM, and the like), ROM, and the like.

The methods and processes described herein may be implemented in software, hardware, or a combination thereof, in different embodiments. In addition, the order of methods can be changed, and various elements can be added, reordered, combined, omitted or otherwise modified. All examples described herein are presented in a non-limiting manner. Various modifications and changes can be made as would be obvious to a person skilled in the art having benefit of this disclosure. Realizations in accordance with embodiments have been described in the context of particular embodiments. These embodiments are meant to be illustrative and not limiting. Many variations, modifications, additions, and improvements are possible. Accordingly, plural instances can be provided for components described herein as a single instance. Boundaries between various components, operations and data stores are somewhat arbitrary, and particular operations are illustrated in the context of specific illustrative configurations. Other allocations of functionality are envisioned and can fall within the scope of claims that follow. Structures and functionality presented as discrete components in the example configurations can be implemented as a combined structure or component. These and other variations, modifications, additions, and improvements can fall within the scope of embodiments as defined in the claims that follow.

In the foregoing description, numerous specific details, examples, and scenarios are set forth in order to provide a more thorough understanding of the present disclosure. It will be appreciated, however, that embodiments of the disclosure can be practiced without such specific details. Further, such examples and scenarios are provided for illustration, and are not intended to limit the disclosure in any way. Those of ordinary skill in the art, with the included descriptions, should be able to implement appropriate functionality without undue experimentation.

References in the specification to “an embodiment,” etc., indicate that the embodiment described can include a particular feature, structure, or characteristic, but every embodiment may not necessarily include the particular feature, structure, or characteristic. Such phrases are not necessarily referring to the same embodiment. Further, when a particular feature, structure, or characteristic is described in connection with an embodiment, it is believed to be within the knowledge of one skilled in the art to affect such feature, structure, or characteristic in connection with other embodiments whether or not explicitly indicated.

Embodiments in accordance with the disclosure can be implemented in hardware, firmware, software, or any combination thereof. Embodiments can also be implemented as instructions stored using one or more machine-readable media, which may be read and executed by one or more processors. A machine-readable medium can include any mechanism for storing or transmitting information in a form readable by a machine (e.g., a computing device or a “virtual machine” running on one or more computing devices). For example, a machine-readable medium can include any suitable form of volatile or non-volatile memory.

In addition, the various operations, processes, and methods disclosed herein can be embodied in a machine-readable medium and/or a machine accessible medium/storage device compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium/storage device.

Modules, data structures, and the like defined herein are defined as such for ease of discussion and are not intended to imply that any specific implementation details are required. For example, any of the described modules and/or data structures can be combined or divided into sub-modules, sub-processes or other units of computer code or data as can be required by a particular design or implementation.

In the drawings, specific arrangements or orderings of schematic elements can be shown for ease of description. However, the specific ordering or arrangement of such elements is not meant to imply that a particular order or sequence of processing, or separation of processes, is required in all embodiments. In general, schematic elements used to represent instruction blocks or modules can be implemented using any suitable form of machine-readable instruction, and each such instruction can be implemented using any suitable programming language, library, application-programming interface (API), and/or other software development tools or frameworks. Similarly, schematic elements used to represent data or information can be implemented using any suitable electronic arrangement or data structure. Further, some connections, relationships or associations between elements can be simplified or not shown in the drawings so as not to obscure the disclosure.

This disclosure is to be considered as exemplary and not restrictive in character, and all changes and modifications that come within the guidelines of the disclosure are desired to be protected.

1. A method for training a language model for enhanced consistency, comprising:
selecting at least a portion of the content data of the language model;
generating reasoning statements in the form of natural language relevant to the selected portion of the content data; and
training the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data.

2. The method of claim 1, wherein the reasoning statements comprise at least one of logically related statements or chain of thought reasoning statements identifying properties of the selected portion of the content data.

3. The method of claim 1, wherein the reasoning statements are generated by at least one of a human or a machine learning model.

4. The method of claim 1, further comprising:
responding to a prompt for information using the trained language model; and
verifying if the response to the prompt is within a threshold of a target response to the prompt.

5. The method of claim 1, further comprising:
receiving at least one prompt originating from a human intended for the language model;
generating an inference in response to the at least one prompt using the language model;
receiving information from the human indicating if the generated inference is within a threshold of a target inference of a response to the at least one prompt; and
if the generated inference is not within the threshold, providing training data to the language model to train the language model to generate an inference that is within the threshold of the target inference.

6. The method of claim 5, wherein the receiving at least one prompt, the generating an inference, the receiving information, and the providing training data are repeated until an inference is generated by the language model that is within the threshold of the target inference.

7. The method of claim 1, further comprising:
receiving a prompt for information;
determining a vector representation for at least a portion of the content data contained in the prompt;
projecting the vector representation into an embedding space in which content data of a language model for which the prompt is intended is embedded;
determining nearest neighbor content data for the vector representation in the embedding space; and
including the nearest neighbor content data in the prompt intended for the language model.

8. A method for generating a logical inference having enhanced consistency for at least a portion of content data, comprising:
receiving a prompt directed to the at least the portion of the content data; and
providing a logical inference in response to the received prompt for the at least the portion of the content data using an associated, trained language model, the language model having been trained by:
generating reasoning statements in the form of natural language relevant to the at least the portion of the content data; and
training the language model using the generated reasoning statements such that a logical inference of the trained language model in response to the received prompt is increased as compared with the logical inference of the language model in response to the same or similar prompt before the training of the language model to enhance the consistency of the language model with respect to at least the at least portion of the content data.

9. An apparatus for training a language model for enhanced consistency, comprising:
a processor; and
a memory accessible to the processor, the memory having stored therein at least one of programs or instructions executable by the processor to configure the apparatus to:
select at least a portion of the content data of the language model;
generate reasoning statements in the form of natural language relevant to the selected portion of the content data; and
train the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data.

10. The apparatus of claim 9, wherein the reasoning statements comprise at least one of logically related statements or chain of thought reasoning statements identifying properties of the selected portion of the content data.

11. The apparatus of claim 9, wherein the reasoning statements are generated by at least one of a human or a machine learning model.

12. The apparatus of claim 9, wherein the apparatus is further configured to:
respond to a prompt for information using the trained language model; and
verify if the response to the prompt is within a threshold of a target response to the prompt.

13. The apparatus of claim 9, wherein the apparatus is further configured to:
receive at least one prompt originating from a human and intended for the language model;
generate an inference in response to the at least one prompt using the language model;
receive information from the human indicating if the generated inference is within a threshold of a target inference of a response to the at least one prompt; and
if the generated inference is not within the threshold, provide training data to the language model to train the language model to generate an inference that is within the threshold of the target inference.

14. The apparatus of claim 13, wherein the receiving at least one prompt, the generating an inference, the receiving information, and the providing training data are repeated until an inference is generated by the language model that is within the threshold of the target inference.

15. A non-transitory computer readable medium having stored thereon at least one program, the at least one program including instructions which, when executed by a processor, cause the processor to perform a method for training a language model for enhanced consistency, comprising:
selecting at least a portion of the content data of the language model;
generating reasoning statements in the form of natural language relevant to the selected portion of the content data; and
training the language model using the generated reasoning statements such that a logical inference of the trained language model in response to a prompt directed to at least the selected portion of the content data is increased as compared with the logical inference of the language model in response to the same or similar prompt before the training of the language model to enhance the consistency of the language model with respect to at least the selected portion of the content data.

16. The non-transitory computer readable medium of claim 15, wherein the reasoning statements comprise at least one of logically related statements or chain of thought reasoning statements identifying properties of the selected portion of the content data.

17. The non-transitory computer readable medium of claim 15, wherein the reasoning statements are generated by at least one of a human or a machine learning model.

18. The non-transitory computer readable medium of claim 15, further comprising:
receiving at least one prompt originating from a human and intended for the language model;
generating an inference in response to the at least one prompt using the language model;
receiving information from the human indicating if the generated inference is within a threshold of a target inference of a response to the at least one prompt; and
if the generated inference is not within the threshold, providing training data to the language model to train the language model to generate an inference that is within the threshold of the target inference.

19. The non-transitory computer readable medium of claim 18, wherein the receiving at least one prompt, the generating an inference, the receiving information, and the providing training data are repeated until an inference is generated by the language model that is within the threshold of the target inference.

20. The non-transitory computer readable medium of claim 15, further comprising:
receiving a prompt for information;
determining a vector representation for at least a portion of the content data contained in the prompt;
projecting the vector representation into an embedding space in which content data of a language model for which the prompt is intended is embedded;
determining nearest neighbor content data for the vector representation in the embedding space; and
including the nearest neighbor content data in the prompt intended for the language model.
